(19) United States
(12) Patent Application Publication
(10) Pub. No.: US 2023/0420316 A1
(43) Pub. Date: Dec. 28, 2023

(54) Integrated Electronic Component

(71) Applicant: Nippon Telegraph and Telephone Corporation, Tokyo (JP)

(72) Inventor: Tadashi Minotani, Musashino-shi, Tokyo (JP)

(21) Appl. No.: 18/252,963

(22) PCT Filed: Nov. 19, 2020
(86) PCT No.: PCT/JP2020/043194

§ 371 Date: May 15, 2023

(51) Int. Cl. H01L 23/14; H01L 23/498; H01L 23/00; H01L 25/065

(52) U.S. Cl. CPC H01L 23/142; H01L 23/49816; H01L 24/16; H01L 25/0655; H01L 2224/16225; H01L 2924/15174; H01L 2924/15311

(57) ABSTRACT

An integrated electronic component includes a lower chip having electrode pads, a molded resin, a rewiring layer, and an upper chip having electrode pads. The rewiring layer has electrode pads that are formed on the lower surface of an insulator and are connected to the electrode pads, electrode pads that are formed on the upper surface of the insulator and are connected to the electrode pads, and interlayer connection conductors that are formed in the insulator and connect the electrode pads and the electrode pads. The electrode pads and the electrode pads are disposed to face each other.

### TECHNICAL FIELD

The present invention relates to an integrated electronic component in which a plurality of components is integrated.

### BACKGROUND ART

Techniques for integrating a plurality of semiconductor chips and electronic components such as a crystal oscillator through processes such as chip rearrangement and rewiring are known these days (see Non Patent Literature 1, for example).

In a component such as a semiconductor chip to be integrated, electric wirings and electrode pads are normally disposed on the upper surface or the lower surface. In a case where a plurality of components is disposed on the same flat surface, wirings for connecting the electrode pads of a plurality of components are produced in the rewiring process. The length of the wirings is proportional to the chip size. When the wirings become longer, parasitic capacitance and parasitic inductance become larger, leading to an increase in power consumption and degradation in frequency characteristics. Therefore, there is a demand for an integration method for reducing the length of wirings between electrode pads of a plurality of components to be integrated.

### CITATION LIST

### Non Patent Literature

Non Patent Literature 1: Yoshiaki SUGIZAKI, “FO-WLP about to be put to practical use as a small-sized, low-cost package”, Japan Electronics and Information Technology Industries Association (JEITA), Semiconductor Technology Roadmap committee (STRJ), 2016, <http://semicon.jeita.or.jp/STRJ/STRJ/2015/2015_06_Jissou.pdf>

### SUMMARY OF INVENTION

### Technical Problem

The present invention has been made to solve the above problem, and aims to provide an integrated electronic component capable of shortening wirings between electrode pads of a plurality of components.

### Solution to Problem

An integrated electronic component according to the present invention includes: a first chip having a first electrode pad on the upper surface of the first chip; a molded resin sealing the first chip; a rewiring layer disposed on the molded resin; and a second chip disposed on the rewiring layer and having a second electrode pad on a lower surface of the second chip. The rewiring layer includes: an insulator; a third electrode pad formed on a lower surface of the insulator, the third electrode pad connected to the first electrode pad; a fourth electrode pad formed on an upper surface of the insulator, the fourth electrode pad connected to the second electrode pad; and an interlayer connection conductor formed in the insulator, the interlayer connection conductor connecting the third electrode pad and the fourth electrode pad. The third electrode pad and the fourth electrode pad connected via the interlayer connection conductor are disposed to face each other.

Further, an example configuration of the integrated electronic component according to the present invention further includes an external connection conductor formed to pass through the molded resin from an upper surface to a lower surface. In the first example configuration, the rewiring layer further includes: a wiring formed on any one of the upper surface, the lower surface, and an inner layer of the insulator, the wiring connected to one of the third electrode pad and the fourth electrode pad; and a fifth electrode pad formed on the lower surface of the insulator, the fifth electrode pad connected to the external connection conductor. At least a part of the wiring is connected to the fifth electrode pad.

Further, in an example configuration of the integrated electronic component according to the present invention, a part of the wiring is a first ground wiring that is formed on the lower surface of the insulator and is connected to the third electrode pad for ground, and is a second ground wiring that is formed on the upper surface of the insulator and is connected to the fourth electrode pad for ground. At least part of the wiring for signals is disposed between the third electrode pad for ground and the fourth electrode pad for ground, and between the first ground wiring and the second ground wiring.

Further, in an example configuration of the integrated electronic component according to the present invention, part of the wiring is a first power-supply wiring that is formed on the lower surface of the insulator and is connected to the third electrode pad for power supply, and is a second power-supply wiring that is formed on the upper surface of the insulator and is connected to the fourth electrode pad for power supply. At least part of the wiring for signals is disposed between the third electrode pad for power supply and the fourth electrode pad for power supply, and between the first power-supply wiring and the second power-supply wiring.

### Advantageous Effects of Invention

According to the present invention, a first chip and a second chip are integrated to face each other. Accordingly, it is possible to shorten the conductor connecting the first chip and the second chip, so that parasitic capacitance and parasitic inductance are reduced. Thus, an increase in power consumption and degradation in frequency characteristics can be prevented.

### BRIEF DESCRIPTION OF DRAWINGS

FIG. 1 is a side view of an integrated electronic component according to an embodiment of the present invention.

FIG. 2 is a plan view of a rewiring layer of an integrated electronic component according to an embodiment of the present invention.

FIG. 3 is a cross-sectional view of a rewiring layer of an integrated electronic component according to an embodiment of the present invention.

### DESCRIPTION OF EMBODIMENTS

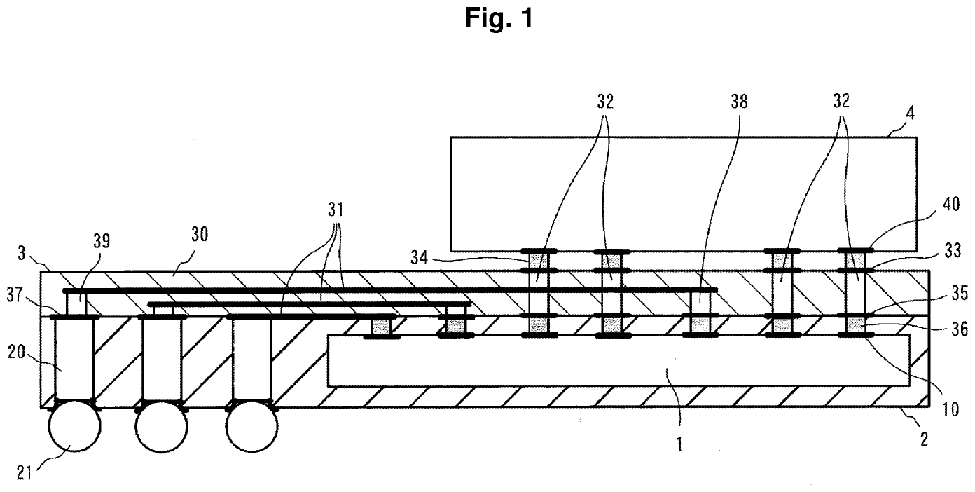

The following is a description of an embodiment of the present invention, with reference to the drawings. FIG. 1 is a side view of an integrated electronic component according to an embodiment of the present invention. FIG. 1 illustrates a rewiring layer and the inside of a mold in a transparent manner.

The integrated electronic component of this embodiment includes a lower chip 1, a molded resin 2 that seals the lower chip 1, a rewiring layer 3 mounted on the molded resin 2, and an upper chip 4 mounted on the rewiring layer 3.

Each of the lower chip 1 and the upper chip 4 is an integrated circuit (IC) chip in which semiconductors are integrated. The integrated electronic component of this embodiment operates with a signal from an external IC (not illustrated).

The base material of the rewiring layer 3 is an insulator 30 formed with a material such as glass or resin, for example. In this insulator 30, wirings 31 connecting the external IC and the lower chip 1, and the interlayer connection conductors 32 (vias) connecting the lower chip 1 and the upper chip 4 are formed.

On the upper surface of the rewiring layer 3, there is an upper chip connection region in which the upper chip 4 is disposed. In the upper chip connection region, upper electrode pads 33 (fourth electrode pad) connected to the interlayer connection conductors 32 are formed. The upper electrode pads 33 and electrode pads 40 on the lower surface of the upper chip 4 are connected via bumps 34 and the like.

On the lower surface of the rewiring layer 3, there is a lower chip connection region in which the lower chip 1 is disposed. In the lower chip connection region, lower electrode pads 35 (third electrode pad) connected to the interlayer connection conductors 32 or the wirings 31 are formed. The lower electrode pads 35 and electrode pads 10 on the upper surface of the lower chip 1 are connected via bumps 36 and the like.

Further, on the lower surface of the rewiring layer 3, there is a region for connecting the integrated electronic component to the outside. In this region, lower electrode pads 37 (fifth electrode pad) are formed. The wirings 31 are at least partially connected to the lower electrode pads 37.

In the molded resin 2, copper pillars 20 connected to the lower electrode pads 37 are formed. On the lower surface of the molded resin 2, ball bumps 21 connected to the pillars 20 are formed. The pillars 20 and the ball bumps 21 form external connection conductors.

The integrated electronic component is connected to an external power supply and the ground via the ball bumps 21, and transmits and receives signals via the ball bumps 21.

The upper electrode pads 33 of the rewiring layer 3 connected to the electrode pads 40 of the upper chip 4, and the lower electrode pads 35 of the rewiring layer 3 connected to the electrode pads 10 of the lower chip 1 are disposed to face each other, and connected via the interlayer connection conductors 32. Thus, the upper electrode pads 33 and the lower electrode pads 35 are connected at the shortest distance.

The wirings 31 of the rewiring layer 3 connected to the electrode pads 10 of the lower chip 1 are disposed avoiding the interlayer connection conductors 32. Note that the wirings 31 disposed in inner layers of the rewiring layer 3 are connected to the lower electrode pads 35 of the rewiring layer 3 via interlayer connection conductors 38. Also, the wirings 31 disposed in the inner layers of the rewiring layer 3 are connected to the lower electrode pads 37 of the rewiring layer 3 via interlayer connection conductors 39.

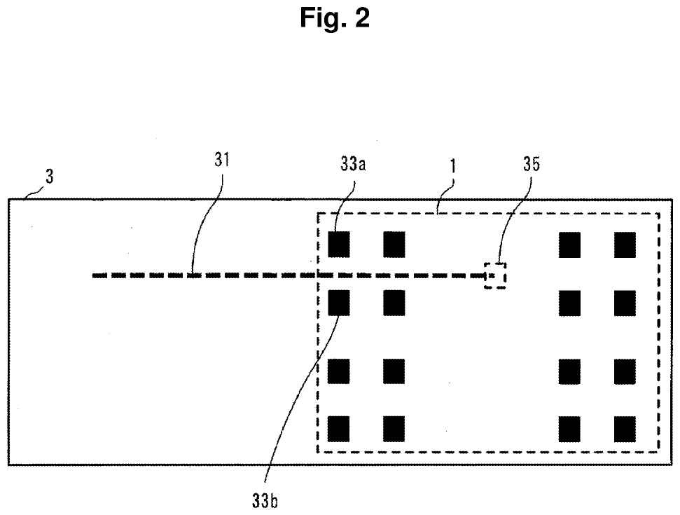

FIG. 2 is a plan view of the rewiring layer 3. Between the upper chip 4 and the lower chip 1, signal transmission and reception, ground connection, and power supply from the lower chip 1 to the upper chip 4 are performed. The wirings 31 connected to an external power supply via the ball bumps 21 are connected to the lower electrode pads 35 for power supply, or to the interlayer connection conductors 32 and 38 for power supply. Likewise, the wirings 31 connected to the ground via the ball bumps 21 are connected to the lower electrode pads 35 for the ground, or to the interlayer connection conductors 32 and 38 for the ground.

On the other hand, the wirings 31 for transmitting and receiving signals between the outside and the lower chip 1 via the ball bumps 21 are disposed avoiding the interlayer connection conductors 32. In the example in FIG. 2, reference numeral 33a indicates an upper electrode pad for signal transmission and reception between the upper chip 4 and the lower chip 1, and reference numeral 33b indicates an upper electrode pad for the ground. As illustrated in FIG. 2, the wirings 31 for transmitting and receiving signals between the outside and the lower chip 1 are disposed avoiding the upper electrode pads 33a and 33b and the interlayer connection conductors 32 disposed below these pads.

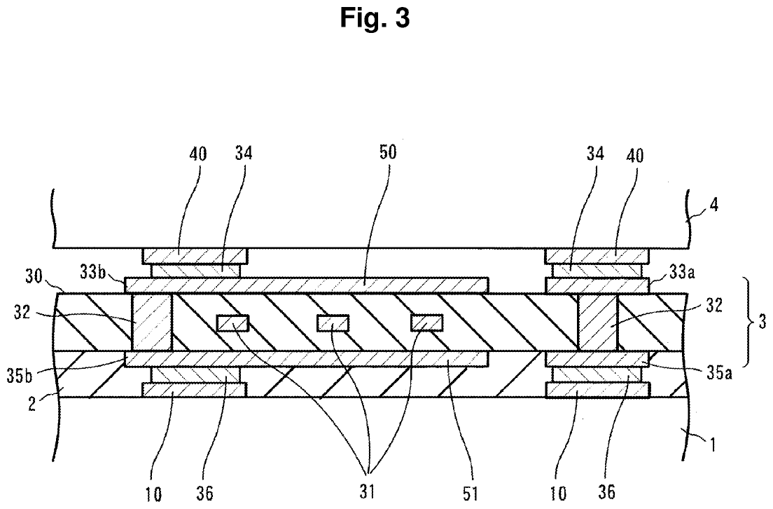

FIG. 3 is a cross-sectional view of the rewiring layer 3. As in FIG. 2, reference numeral 33a indicates an upper electrode pad for signal transmission and reception, reference numeral 33b indicates an upper electrode pad for the ground, reference numeral indicates a lower electrode pad for signal transmission and reception, and reference numeral 35b indicates a lower electrode pad for the ground.

In a case where many wirings 31 for radio-frequency signals are connected to different electrode pads 10 of the lower chip 1, the wirings 31 for radio-frequency signals are disposed between the upper electrode pad 33b and the lower electrode pad 35b for the ground, as illustrated in FIG. 3.

In the example in FIG. 3, the upper electrode pad 33b is connected to a ground wiring 50 on the upper surface of the rewiring layer 3, and the lower electrode pad 35b is connected to a ground wiring 51 on the lower surface of the rewiring layer 3. Three wirings 31 are then disposed between the upper electrode pad 33b and the lower electrode pad 35b, and between the ground wiring 50 and the ground wiring 51. The upper electrode pad 33b and the lower electrode pad 35b are connected to each other via an interlayer connection conductor 32.

Thus, in this embodiment, strip transmission lines can be formed with the wirings 31, the upper electrode pad 33b, the lower electrode pad 35b, and the ground wirings 50 and 51, and a large number of wirings 31 can be provided in inner layers of the rewiring layer 3, without an increase in the length of the conductors connecting the upper chip 4 and the lower chip 1.

Although not illustrated in FIG. 3, there is a power supply wiring connected to the upper electrode pads 33 for power supply on the upper surface of the rewiring layer 3, and there is a power supply wiring connected to the lower electrode pads 35 for power supply on the lower surface of the rewiring layer 3. Therefore, the wirings 31 may be disposed between the upper electrode pads 33 for power supply and the lower electrode pads 35 for power supply, and between the power supply wiring on the upper surface and the power supply wiring on the lower surface of the rewiring layer 3.

The integrated electronic component of this embodiment is produced as follows. First, the rewiring layer 3 in which the wirings 31, the upper electrode pads 33, the lower electrode pads 35 and 37, the interlayer connection conductors 32, 38, and 39, and the like are formed on both surfaces and in inner layers of the insulator 30 is produced.

Next, the pillars 20 are formed on the lower electrode pads 37 so that the surface of the rewiring layer 3 on which the lower electrode pads 35 and 37 are formed faces upward, and the lower chip 1 is mounted on the rewiring layer 3. As described above, the lower electrode pads 35 of the rewiring layer 3 and the electrode pads 10 of the lower chip 1 are connected via the bumps 36. The molded resin 2 is then formed to seal the lower chip 1. The molded resin 2 is ground so that the pillars 20 are exposed, and the ball bumps 21 are formed on the exposed portions of the pillars 20.

Next, the upper chip 4 is mounted on the rewiring layer 3 so that the surface of the rewiring layer 3 on which the upper electrode pads 33 are formed faces upward. As described above, the upper electrode pads 33 of the rewiring layer 3 and the electrode pads 40 of the upper chip 4 are connected via the bumps 34.

Thus, production of the integrated electronic component is completed.

Note that, in this embodiment, at least the wirings 31 are at least partially connected to the lower electrode pads 35 of the rewiring layer 3. However, the wirings 31 may be at least partially connected to the upper electrode pads 33 of the rewiring layer 3.

Further, in this embodiment, there is a single lower chip 1 and a single upper chip 4. However, a plurality of lower chips 1 and/or upper chips 4 may be integrated.

### INDUSTRIAL APPLICABILITY

The present invention can be applied to a technique for integrating a plurality of components.

### REFERENCE SIGNS LIST

1 lower chip
2 molded resin
3 rewiring layer
4 upper chip
10, 33, 35, 37, 40 electrode pad
20 pillar
21 ball bump
30 insulator
31 wiring
32, 38, 39 interlayer connection conductor
33, 35, 37, 40 electrode pad
34, 36 bump
50, 51 ground wiring

1. An integrated electronic component comprising:
a first chip having a first electrode pad disposed on a surface thereof;
a rewiring layer disposed on the surface of the first chip where the first electrode paid is disposed; and
a second chip disposed on the rewiring layer and having a second electrode pad on a surface facing the rewiring layer,
wherein
the rewiring layer includes:
an insulator layer;
a third electrode pad disposed on a first surface of the insulator layer facing the first chip, the third electrode pad connected to the first electrode pad;
a fourth electrode pad disposed on a second surface of the insulator layer facing the second chip, the fourth electrode pad connected to the second electrode pad; and
an interlayer connection conductor formed in the insulator layer, the interlayer connection conductor connecting the third electrode pad and the fourth electrode pad to each other,
wherein
the third electrode pad and the fourth electrode pad are disposed at corresponding positions on the first surface and the second surface of the insulator layer, respectively.

2. The integrated electronic component according to claim 1,
wherein
the rewiring layer further includes:
a wiring formed on any one of the first surface, the second surface, and an inner layer of the insulator layer, the wiring connected to one of the third electrode pad and the fourth electrode pad.

3. The integrated electronic component according to claim 2, wherein
the wiring includes:
a first ground wiring for ground that is formed on the first surface of the insulator layer and is connected to the third electrode pad,
a second ground wiring for ground that is formed on the second surface of the insulator layer and is connected to the fourth electrode pad,
a first signal wiring for signals that is disposed between the third electrode pad and the fourth electrode pad, and
a second signal wiring for signals that is disposed between the first ground wiring and the second ground wiring.

4. The integrated electronic component according to claim 2, wherein
the wiring includes:
a first power-supply wiring for power supply that is formed on the first surface of the insulator layer and is connected to the third electrode pad,
a second power-supply wiring for power supply that is formed on the second surface of the insulator layer and is connected to the fourth electrode pad,
a first signal wiring for signals that is disposed between the third electrode pad and the fourth electrode pad, and
a second signal wiring for signals that is disposed between the first power-supply wiring and the second power-supply wiring.

5. The integrated electronic component according to claim 1, further comprising:
a sealing member sealing the first chip; and
a connection conductor passing through the sealing member,
wherein
the rewiring layer further includes:
a wiring formed on any one of the first surface, the second surface, and an inner layer of the insulator layer, the wiring connected to one of the third electrode pad and the fourth electrode pad; and
a fifth electrode pad disposed on the first surface of the insulator layer, the fifth electrode pad connected to the connection conductor, and
at least a part of the wiring is connected to the fifth electrode pad.

6. The integrated electronic component according to claim 1, wherein the third electrode pad and the fourth electrode pad are connected via the interlayer connection conductor at the shortest distance.
